(19) United States
(12) Patent Application Publication
(10) Pub. No.: US 2022/0237338 A1
(43) Pub. Date: Jul. 28, 2022

(54) RANK-CORRELATED PATTERNS FOR GUIDING HARDWARE DESIGN

(71) Applicant: EMC IP Holding Company LLC, Hopkinton, MA (US)

(72) Inventors: Paulo Abelha Ferreira, Rio de Janeiro (BR); Adriana Bechara Prado, Niterói (BR); Jonas Furtado Dias, Beecroft (AU)

(21) Appl. No.: 17/160,566

(22) Filed: Jan. 28, 2021

(51) Int. Cl. G06F 30/20; G06K 9/62; G06F 17/18

(52) U.S. Cl. CPC G06F 30/20; G06F 17/18; G06K 9/6267

(57) ABSTRACT

A system and method for implementing design cycles for developing a hardware component including receiving sets of experimental data, each of set experimental data resulting from an application of a set of variables to the hardware component during a common or a different design cycle of the hardware component, where each variable represents an aspect of the hardware component, determining discretized classes of the experimental data based on one or more quality metrics, and obtaining statistical measurements of the variables to determine correlations between the discretized classes of the quality metrics and the statistical measurements of variables for determining a pattern of the quality metrics to reduce the number of design cycles implemented on the hardware component during the developing of the hardware component.

### BACKGROUND

Engineering product development cycles can be design-intensive. Key product, manufacturing, and testing features require considerable testing, typically consuming numerous cycles before converging to a stable and workable design. Generally, the greater the number of design cycles, the higher the costs attributed to the product design.

### SUMMARY

In general, an aspect of the invention includes a method of receiving sets of experimental data, each set of experimental data resulting from an application of a set of variables to the hardware component during a common design cycle or a different design cycle of the hardware component, each variable representing an aspect of a hardware component or a fabrication process applied to the hardware component, determining discretized classes of one or more quality metrics, wherein the discretized classes of the quality metrics are determined independently from a determination of discretized classes of a different quality metric of the one or more quality metrics, wherein the discretized classes of the quality metrics are a classification of the quality metrics in an order of values of the classes of the experimental data, and obtaining statistical measurements of the variables to determine correlations between the discretized classes of the quality metrics and the statistical measurements of the variables to reduce the number of design cycles implemented on the hardware component during the developing of the hardware component.

In general, in one aspect, the invention relates to a system that includes a processor and memory that includes instructions which, when executed by the processor, performs a method. The method includes receiving sets of experimental data, each set of experimental data resulting from an application of a set of variables to the hardware component during a common design cycle or a different design cycle of the hardware component, each variable representing an aspect of a hardware component or a fabrication process applied to the hardware component, determining discretized classes of one or more quality metrics, wherein the discretized classes of the quality metrics are determined independently from a determination of discretized classes of a different quality metric of the one or more quality metrics, wherein the discretized classes of the quality metrics are a classification of the quality metrics in an order of values of the classes of the experimental data, and obtaining statistical measurements of the variables to determine correlations between the discretized classes of the quality metrics and the statistical measurements of the variables to reduce the number of design cycles implemented on the hardware component during the developing of the hardware component.

In general, in one aspect, the invention relates to a non-transitory computer readable medium (CRM). The non-transitory CRM includes computer readable program code, which when executed by a computer processor, enables the computer processor to perform a method for implementing design cycles for developing a hardware component. The method includes

receiving sets of experimental data, each set of experimental data resulting from an application of a set of variables to the hardware component during a common design cycle or a different design cycle of the hardware component, each variable representing an aspect of a hardware component or a fabrication process applied to the hardware component, determining discretized classes of one or more quality metrics, wherein the discretized classes of the quality metrics are determined independently from a determination of discretized classes of a different quality metric of the one or more quality metrics, wherein the discretized classes of the quality metrics are a classification of the quality metrics in an order of values of the classes of the experimental data, and obtaining statistical measurements of the variables to determine correlations between the discretized classes of the quality metrics and the statistical measurements of the variables to reduce the number of design cycles implemented on the hardware component during the developing of the hardware component.

Other aspects of the invention will be apparent from the following description and the appended claims.

### BRIEF DESCRIPTION OF DRAWINGS

FIG. 1 shows an example system in accordance with one or more embodiments of the disclosure described herein.

FIG. 2 shows a flowchart describing a method for implementing design cycles for developing a hardware component in accordance with one or more embodiments of the disclosure disclosed herein.

FIG. 3 shows an exemplary set of experimental data for a quality metric in accordance with one or more embodiments of the disclosure disclosed herein.

FIGS. 4-9 show exemplary tables and graphs generated by the components of FIG. 1 in accordance with one or more embodiments of the disclosure disclosed herein.

FIG. 10 shows an example host in accordance with one or more embodiments described herein.

### DETAILED DESCRIPTION

Whether designing an entire hardware system or components thereof, engineering product development typically entails an initial design cycle, where an initial design is subjected to various test environments, and observed output exhibiting the behavior of the initial design is collected and evaluated for further design cycles. In subsequent design cycles, the steps are repeated in that adjustments to the design of the immediately preceding design cycle are made, and the revised design is subjected to further testing, observing outputs are collected and analyzed for further fine-tuning of the design. These cycles are repeated until the product design exhibits a desired behavior-converges.

In many cases, designers are particularly interested in the behavior of certain design features, quality metrics, in varying environments. For example, the designer of a semiconductor product may be particularly interested in yield (an example of a quality metric), and thickness of the semiconductor layers, and/or the composition of the solution used in manufacturing to clean, oxidize, or mask parts or the entirety of the layers (examples of variables). Most desirably, costs associated with product design are best minimized but the requisite numerous design cycles are at times at odds with maintaining minimal product design and experimental costs. Achieving the desired level of design quality while minimizing costs, at times, presents even more of a challenge.

To address one or more of the aforementioned challenges, consider a design cycle in accordance with one or more embodiments of the invention in which a controlled set of parameters or variables is initially selected for building a new set of experiments for designing, manufacturing, or building prototypes. During an initial cycle, experimental tests with the initial set of parameters is applied to the design and the values of variables and the quality metrics are collected. Next, a different set of parameters is applied to the design and the quality metrics and the values of the variables are once again collected. At a next cycle, another set of parameters, different than the initial two sets, is applied to the design and the quality metrics and the values of the variables are again collected. The cycle is repeated until the design converges. Each experimental and data analysis cycle incurs high cost, valuable engineering time, and resources. Hardware design in particular requires careful selection of physical components, configurations, and fabrication processes to achieve a desired design quality level. A clear plan that guides posterior cycles to converge into a high-quality hardware design as measured by relevant metrics can be cost-effective and less resource intensive.

Selecting the best, or near-best, set of parameters (variables) to build a new batch of experimental tests to be applied to the product design can help reduce product development costs because fewer design cycles are required.

In some embodiments of the invention, product development is implemented with a high-quality design even in the face of a few challenges, namely, a vast number of parameters, a small number of experimental samples, and fewer number of design cycles. Rank-correlated patterns are mined from experiments on the hardware design to find features (or variables), and combinations thereof, that correlate well with quality metrics. The effect of noise is reduced or nearly eliminated because experimental data is pre-processed prior to rank-correlation mining.

An association between a selection of features and a change (i.e., increase or decrease) in the quality metrics can help guide design choices. The quality metrics are defined by a designer of a hardware component under development. For instance, consider the case where the quality of a hardware component is measured with a set of metrics, Yi={Y1, . . . , Ym} obtained from a series of experiments. Consider that the value of each Yi depends on designing parameters, or features, also referred to herein as “variables”, {X1, . . . , Xn}. The objective is to identify which subset of {X1, . . . , Xn}, and the ranges of values thereof, have the strongest influence on an increase or decrease of each Yi. By so doing, hardware designers can more easily select the hardware configurations and specifications that lead to the highest design quality and repeated experimentation using only a subset of configurations, therefor reducing the number of design cycles and potentially reducing the overall design costs and requisite design resources.

One or more embodiments of the invention is centered around mining for frequent rank-correlated patterns. After applying a given set of experimental tests (or observations) to the hardware component using a distinct set of parameters or variables, the quality metrics are classified for subsequent finding of patterns of higher (or lower) thresholds or ranges of a feature, Xi, and mining for a higher (or lower) quality metric, Yi. Such patterns are used to guide new relevant experiments, configurations and processes. The method helps the experimental cycle converge on a desirable set of features, thus, decreasing product development costs while maintaining product design quality.

In some embodiments of the invention, the experimental data is preprocessed prior to mining for patterns to reduce the effect of noise introduced from continuous observation and collection of experimental data, or points, with each set of variables. That is, rather than performing a comparison of raw experimentation data, methods and systems perform a comparison of statistical data relating to the variables, based on the experimentation data, and the comparisons are mined for correlated patterns. Accordingly, the adverse effects of one-offs and anomalies—noise effects—on raw data comparison are minimized and in some cases eliminated.

Various embodiments of the disclosure are described below.

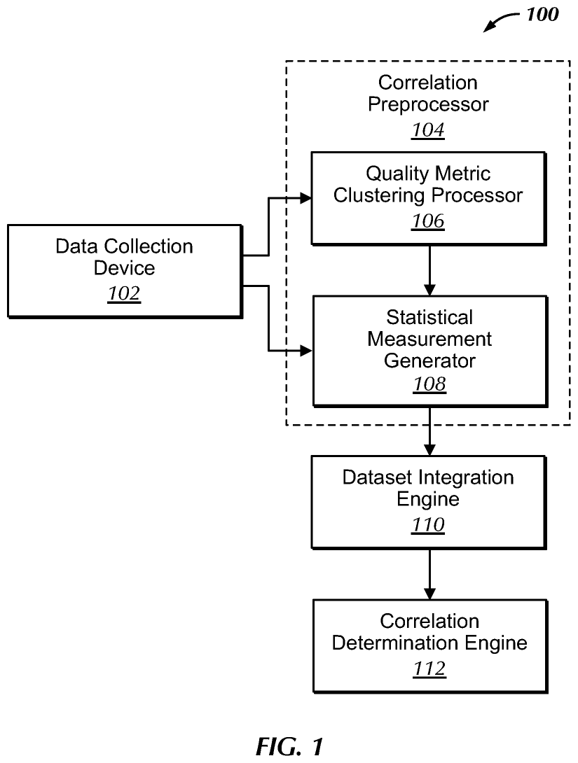

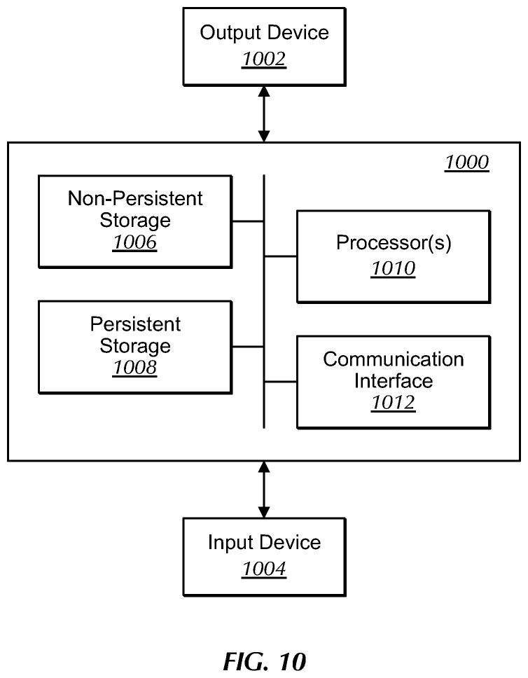

FIG. 1 illustrates an exemplary hardware component development system (100), according to one or more embodiments of the disclosure. As shown in FIG. 1, the hardware component development system (100) includes a data collection device (102), a correlation preprocessor (104), a dataset integration engine (110), and a correlation determination engine (112). The correlation preprocessor (104) includes a quality metric clustering processor (106) and a statistical measurement generator (108). Further details of each of the foregoing components is presented below with reference to FIG. 10.

In an embodiment of the invention, the hardware component development system (100) is an implementation of design cycles for developing a hardware component. For example, and without limitation, the hardware component may be a piece of a hardware system, such as a semiconductor device of a graphics subsystem of a computer or network system or a circuitry portion within the semiconductor device.

In an embodiment of the invention, the data collection device (102) is operationally coupled to the correlation preprocessor (104), which is in turn operationally coupled to the dataset integration engine (110), which is in turn operationally coupled to the correlation determination engine (112). In some embodiments of the invention, the quality metric clustering processor (106) is operationally coupled to the data collection device (102) and to the statistical measurement generator (108), which is in turn coupled to the dataset integration engine (110).

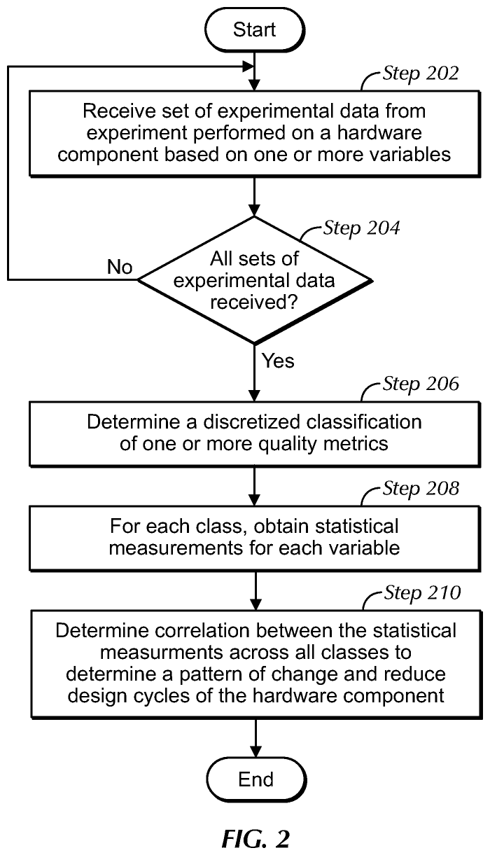

In an embodiment of the invention, the data collection device (102) may be implemented using one or more computing devices (e.g., see FIG. 10) functionally equipped to output sets of experimental data generated from a hardware component undergoing experimentation. Each set of experimental data is based on a distinct set of variables corresponding to the hardware component or a fabrication aspect of the hardware component where the “set” is a number including the number “1” and higher. The experimental data is a collection of variables, the features used in the hardware component fabrication and design processes, and the corresponding collected quality metric(s). The variables relate to corresponding quality metrics in that they result from applying different features on the hardware component or its fabrication and observing and collecting the resulting quality metric(s). A nonlimiting example of sets of experimental data, without taking into account any classifications of the quality metrics, is presented by the collection of all data points shown in the graph of FIG. 3. The data collection device (102) is further functionally equipped to one or more quality metric(s) ultimately discretized into quality metric classes by the quality metric clustering processor (106). Based on the experimental data collected by the data collection device (102), the data collection device (102) provides variables, in the form of raw values, to the statistical measurement generator (108) for calculating distributions of the raw variables values in relation to each quality metric(s) class. Further, details of data collection device (102) is also presented below with reference to FIGS. 2-9.

In one embodiment of the disclosure, the data collection device (102) is a physical or virtual device that may be used for performing various embodiments of the disclosure. The physical device may correspond to any physical system with functionality to implement one or more embodiments of the disclosure. For example, the physical device may be a device or a part of or incorporated in a system with at least one or more processor(s) and memory.

Alternatively, the physical device may be a special purpose computing device that includes one or more application-specific processor(s) (or hardware) configured to only execute embodiments of the disclosure. In such cases, the physical device may implement embodiments of the disclosure in hardware as a family of circuits and may retain limited functionality to receive input and generate output in accordance with various embodiments of the disclosure. In addition, such computing devices may use a state-machine to implement various embodiments of the disclosure.

In another embodiment of the disclosure, the physical device may correspond to a computing device that includes one or more general purpose processor(s) and one or more application-specific processor(s) (or hardware). In such cases, one or more portions of the disclosure may be implemented using the operating system and general purpose processor(s), while one or more portions of the disclosure may be implemented using the application-specific processor(s) (or hardware).

In one embodiment of the disclosure, the data collection device (102) includes executable instructions (stored in a non-transitory computer readable medium (not shown), which when executed, enable the data collection device (102) to perform one or more methods described below (see e.g., FIGS. 2-9).

Alternatively, the physical device may be a special purpose computing device that includes one or more application-specific processor(s) (or hardware) configured to only execute embodiments of the disclosure. In such cases, the physical device may implement embodiments of the disclosure in hardware as a family of circuits and may retain limited functionality to receive input and generate output in accordance with various embodiments of the disclosure. In addition, such computing devices may use a state-machine to implement various embodiments of the disclosure.

In another embodiment of the disclosure, the physical device may correspond to a computing device that includes one or more general purpose processor(s) and one or more application-specific processor(s) (or hardware). In such cases, one or more portions of the disclosure may be implemented using the operating system and general purpose processor(s), while one or more portions of the disclosure may be implemented using the application-specific processor(s) (or hardware).

In one embodiment of the invention, the data collection device (102) includes executable instructions (stored in a non-transitory computer readable medium (not shown)), which when executed, enable the data collection device (102) to perform one or more methods described below (see e.g., FIGS. 2-9).

In one embodiment of the disclosure, the correlation preprocessor (104) generally generates statistical measurements of identified variables or features for each class of each of the quality metrics selected by a designer of the hardware component under development. More specifically, the quality metric clustering processor (106) of the correlation preprocessor (104) may be implemented using one or more computing devices functionally equipped to receive the sets of experimental data and to process the sets of experimental data to group or cluster the experimental data based on one or more quality metric. Continuing with the above example of the development of a semiconductor device, a quality metric may be, without limitation, the desired yield of the semiconductor during fabrication, i.e., the percentage of semiconductor devices of a wafer that meet certain expected operational characteristics, the desired thickness of the geometry of various features of the semiconductor, such as the thickness of each layer of the semiconductor device, or the desired uniformity of evenness of the semiconductor file thickness. Examples of variables, without limitation, include the semiconductor deposition, e.g., thermal oxidation thickness; wet etching steps, such as the chemicals and quantity thereof used for the wet etching process, bath solution concentration of the mixture of the chemical components, the bath duration, and the temperature used during the wet etching process; and the doping temperature during the annealing process of the semiconductor device fabrication.

In an embodiment of the invention, by clustering the quality metrics, the quality metric clustering processor (106) effectively discretizes the quality metric classes (QMCs).

In one embodiment of the disclosure, the quality metric clustering processor (106) is a physical or virtual device that may be used for performing various embodiments of the disclosure. The physical device may correspond to any physical system with functionality to implement one or more embodiments of the disclosure.

Alternatively, the physical device may be a special purpose computing device that includes one or more application-specific processor(s) (or hardware) configured to only execute embodiments of the disclosure. In such cases, the physical device may implement embodiments of the disclosure in hardware as a family of circuits and may retain limited functionality to receive input and generate output in accordance with various embodiments of the disclosure. In addition, such computing devices may use a state-machine to implement various embodiments of the disclosure.

In another embodiment of the disclosure, the physical device may correspond to a computing device that includes one or more general purpose processor(s) and one or more application-specific processor(s) (or hardware). In such cases, one or more portions of the disclosure may be implemented using the operating system and general purpose processor(s), while one or more portions of the disclosure may be implemented using the application-specific processor(s) (or hardware).

In one embodiment of the invention, the quality metric clustering processor (106) includes executable instructions (stored in a non-transitory computer readable medium (not shown)), which when executed, enable the quality metric clustering processor (106) to perform one or more methods described below (see e.g., FIGS. 2-9).

In one embodiment of the disclosure, the statistical measurement generator (108) of the correlation preprocessor (104) may be implemented using one or more computing devices functionally equipped to obtain probabilistic distributions of the raw form of the values of the variables in relation to quality metric classes. More specifically, the statistical measurement generator (108) may receive experimental data, as described above, from the data collection device (102) and the quality metric clustering processor (106). The data collection device (102) provides the raw variables' values and quality metric clustering processor (106) provides the quality metrics. The statistical measurement generator (108) generates distributions for each of the classes of the quality metric(s) and provides the distributions to the dataset integration engine (110) for storage, as described in further detail below with respect to the dataset integration engine (110). According to generating a dataset corresponding to the classes of the quality metrics to the statistics measurements of the variables.

The statistical measurements (distributions) are generated in relation to quality metric(s) classes (QMCs)—for each quality metric(s) class, the statistical measurement generator (108) generates the distribution of a variable by computing a statistic. Examples of statistics, without limitation, include mean, median, variance, and percentiles.

Statistical measurements are not limited to mean, median, variance and percentiles and may be based on any kind of statistic that summarizes in a single number the distribution of raw values of variables and that yields a summary of the experimental data in a meaningful manner. For example, the statistical measurements may provide a summary of the experimental data that ultimately may provide insight into the capability of the number of mistakes that a computer system can afford a corresponding hard drive to make or a tolerable semiconductor yield factor.

For every quality metric, the quality metric clustering processor (106) determines a class or cluster for each of the one or more quality metrics and the statistical measurement generator (108) receives the raw values of variables from the data collection device (102) and discretized the quality metrics received from the quality metric clustering processor (106). The statistical measurement generator (108) obtains statistical measurements of each variable's distribution in relation to each class of the one or more quality metrics. For example, a designer my select four levels of a quality metric classification: excellent, very good, acceptable and unacceptable, where excellent and very good are indicative of value. The statistical measurements of every feature for every identified class for each quality metric may be analyzed to ultimately determine which of the features are, for example, increasing with the increasing order of the class.

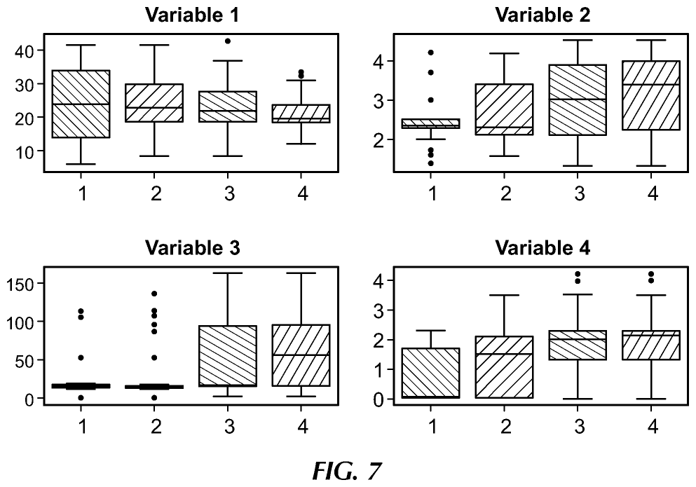

An example output, without limitation, generated by the statistical measurement generator (108) is provided in FIG. 7.

In one embodiment of the disclosure, the statistical measurement generator (108) is a physical or virtual device that may be used for performing various embodiments of the disclosure. The physical device may correspond to any physical system with functionality to implement one or more embodiments of the disclosure.

Alternatively, the physical device may be a special purpose computing device that includes one or more application-specific processor(s) (or hardware) configured to only execute embodiments of the disclosure. In such cases, the physical device may implement embodiments of the disclosure in hardware as a family of circuits and may retain limited functionality to receive input and generate output in accordance with various embodiments of the disclosure. In addition, such computing devices may use a state-machine to implement various embodiments of the disclosure.

In another embodiment of the disclosure, the physical device may correspond to a computing device that includes one or more general purpose processor(s) and one or more application-specific processor(s) (or hardware). In such cases, one or more portions of the disclosure may be implemented using the operating system and general purpose processor(s), while one or more portions of the disclosure may be implemented using the application-specific processor(s) (or hardware).

In one embodiment of the invention, the statistical measurement generator (108) includes executable instructions (stored in a non-transitory computer readable medium (not shown)), which when executed, enable the statistical measurement generator (108) to perform one or more methods described below (see e.g., FIGS. 2-9).

In one embodiment of the invention, the dataset integration engine (110) may be implemented using one or more computing devices functionally equipped to generate a dataset associating each quality metric(s) class to respective statistical measurements. In an embodiment of the invention, the dataset integration engine (110) consolidates the distributions of the variables and the quality metric classes received from the statistical measurement generator (108) and temporarily stores the consolidated information in a database or a storage. For example, the dataset integration engine (110) may temporarily store the consolidated information, the dataset, in a non-persistent memory (1006), FIG. 10, for subsequent use by the correlation determination engine (112). The dataset generated by the dataset integration engine (110) corresponds to the classes of the quality metrics of the statistics measurements of the variables from the statistical measurement generator (108). The dataset integration engine (110) provides the dataset to the correlation determination engine (112) for applying a rank-correlated mining algorithm to mine for patterns of rank correlation.

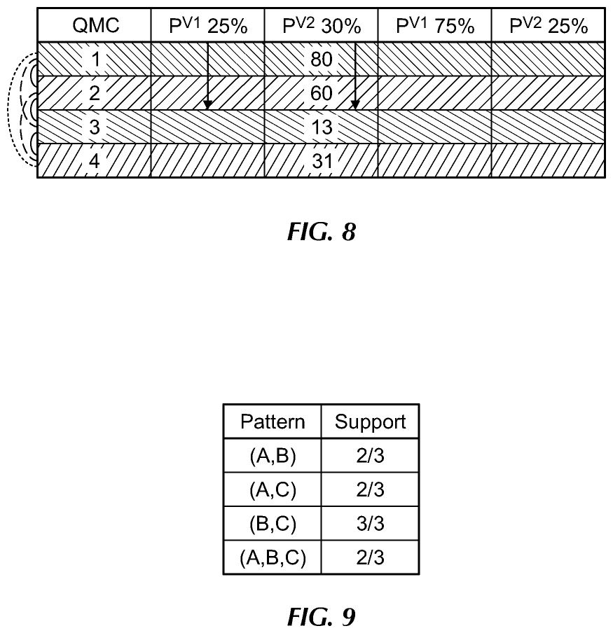

A non-limiting example of the output generated by the dataset integration engine (110) is provided by the table of FIG. 8 and discussed further below.

In one embodiment of the disclosure, the dataset integration engine (110) is a physical or virtual device that may be used for performing various embodiments of the disclosure. The physical device may correspond to any physical system with functionality to implement one or more embodiments of the disclosure.

Alternatively, the physical device may be a special purpose computing device that includes one or more application-specific processor(s) (or hardware) configured to only execute embodiments of the disclosure. In such cases, the physical device may implement embodiments of the disclosure in hardware as a family of circuits and may retain limited functionality to receive input and generate output in accordance with various embodiments of the disclosure. In addition, such computing devices may use a state-machine to implement various embodiments of the disclosure.

In another embodiment of the disclosure, the physical device may correspond to a computing device that includes one or more general purpose processor(s) and one or more application-specific processor(s) (or hardware). In such cases, one or more portions of the disclosure may be implemented using the operating system and general purpose processor(s), while one or more portions of the disclosure may be implemented using the application-specific processor(s) (or hardware).

In one embodiment of the invention, the dataset integration engine (110) includes executable instructions (stored in a non-transitory computer readable medium (not shown)), which when executed, enable the dataset integration engine (110) to perform one or more methods described below (see e.g., FIGS. 2-9).

In one embodiment of the disclosure, the correlation determination engine (112) may be implemented using one or more computing devices functionally equipped to perform mining to determine correlations between the discretized classes generated by the quality metric clustering processor (106) for determining a pattern of the quality metrics in an effort to reduce the number of design cycles implemented for developing a hardware component.

In one embodiment of the disclosure, the correlation determination engine (112) is a physical or virtual device that may be used for performing various embodiments of the disclosure. The physical device may correspond to any physical system with functionality to implement one or more embodiments of the disclosure.

Alternatively, the physical device may be a special purpose computing device that includes one or more application-specific processor(s) (or hardware) configured to only execute embodiments of the disclosure. In such cases, the physical device may implement embodiments of the disclosure in hardware as a family of circuits and may retain limited functionality to receive input and generate output in accordance with various embodiments of the disclosure. In addition, such computing devices may use a state-machine to implement various embodiments of the disclosure.

In another embodiment of the disclosure, the physical device may correspond to a computing device that includes one or more general purpose processor(s) and one or more application-specific processor(s) (or hardware). In such cases, one or more portions of the disclosure may be implemented using the operating system and general purpose processor(s), while one or more portions of the disclosure may be implemented using the application-specific processor(s) (or hardware).

In one embodiment of the invention, the correlation determination engine (112) includes executable instructions (stored in a non-transitory computer readable medium (not shown)), which when executed, enable the correlation determination engine (112) to perform one or more methods described below (see e.g., FIGS. 2-9).

FIG. 2 shows a flowchart describing a method for implementing design cycles for developing a hardware component in accordance with one or more embodiments described herein. The method of FIG. 2 may be performed by, for example, by the correlation preprocessor (104), dataset integration engine (110) and the correlation determination engine (112) of FIG. 1. Other components not illustrated in FIG. 1 may perform or assist in performing the method of FIG. 2 without departing from the disclosure.

While the various steps in the flowchart shown in FIG. 2 are presented and described sequentially, one of ordinary skill in the relevant art, having the benefit of this Detailed Description, will appreciate that some or all of the steps may be executed in different orders, that some or all of the steps may be combined or omitted, and/or that some or all of the steps may be executed in parallel.

In step 202, a quality metric clustering processor (e.g., 106, FIG. 1) receives a set of experimental data from a data collection device (e.g., 102, FIG. 1). Without limitation, an example of a set of experimental data is shown with a symbol-colored set of point (e.g., square, triangular, . . . ) in the graph of FIG. 3. In the graph of FIG. 3, the x-axis represents the number of experimental data (or points) and the y-axis represents the values of a quality metric. It is understood that while only one quality metric is represented in FIG. 3, various embodiments of the invention are not limited to one quality metric and more than quality metric may be represented by the graph of FIG. 3 and employed by the system. A set of experimental data may be derived from the application of one or more parameters or variables to a hardware component under development. For example, continuing from the above example with yield as a desired feature or quality metric, a variable may be the composition of the solution used during the annealing process part of the fabrication of the semiconductor device.

In some embodiments, the set of experimental data results from an application of a set of variables to a hardware component under development or the fabrication of the hardware component. In some embodiments, the set of experimental data is collected by a data collection device (e.g., 102, FIG. 1) during a common design cycle or in a different design cycle of the hardware component design. Each variable represents an aspect of the hardware component or an aspect of a fabrication process applied to the hardware component.

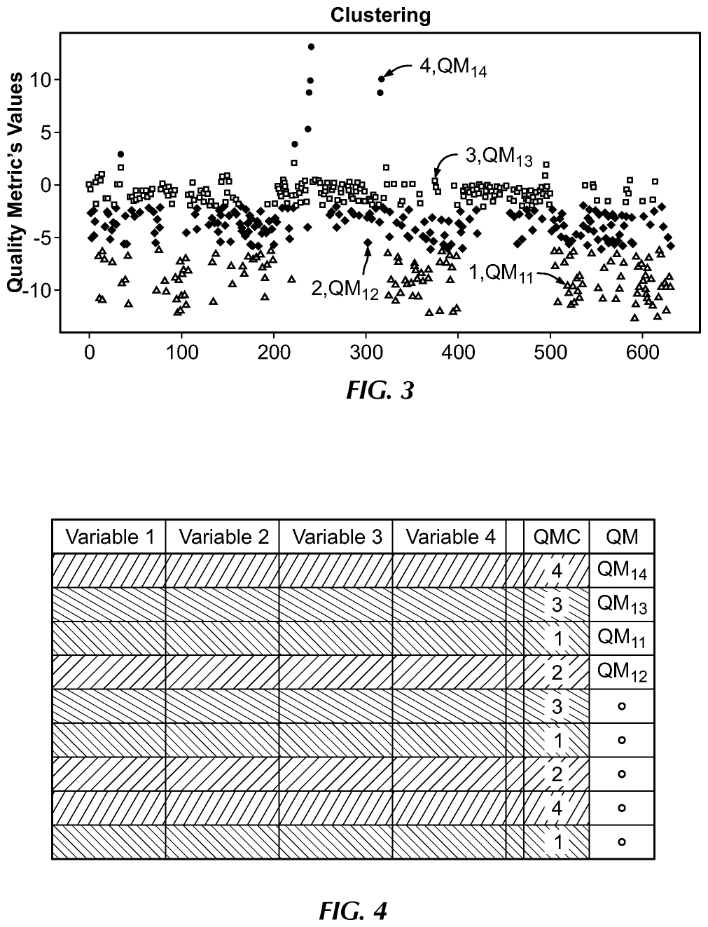

In Step 204, the quality metric clustering processor determines whether additional sets of experimental data are received from the data collection device and if so, the process returns to and performs steps 202 and 204. Otherwise, in response to determining there are no further sets of experimental data, the process proceeds to step 206. For example, in the graph of FIG. 3, the process repeats steps 202 and 204 four times to account for receiving four sets of experimental data, each set shown by a distinct color in FIG. 3. At the time the quality metric clustering processor receives the sets of experimental data, the data is not classified according to distinct colors as shown in FIG. 3. Rather, the data for all four sets may be similar to the points shown in FIG. 3 in the absence of any color. Stated differently, there is no unique criterion for differentiating the different points at step 206. The quality metric clustering processor determines a discretized classification of one or more quality metrics. For example, the data in the graph of FIG. 3 is classified pursuant to levels of value, as discussed above (e.g., excellent, very good, acceptable, and unacceptable). The discretized classification transforms a continuous quality metric into a discrete quality metric therefore eliminating or at least reducing the noise level associated with each quality metric. In the example of FIG. 3 and those shown in subsequent figures (FIGS. 4-9), for the purpose of clarity of illustration, the number of quality metrics is limited to one. It is understood however, that the system may employ more than one quality metric. Similarly, in the examples of FIGS. 4-9, the number of variables is limited to four in the interest of simplicity of illustration yet it is understood that any number of variables may be employed, as discussed above. Noteworthy, generally, the greater the number of variables, the more complex the algorithmic calculations required to be performed. Also, noteworthy, the number of experimental data may affect the detected pattern in that the fewer the data points, the less accurate the detected pattern, and vice versa.

The quality metric clustering processor may determine the discretized classes of the quality metrics where the discretized classes of the quality metrics are determined independently from a determination of discretized classes of a different quality metric. The discretized classes of the quality metrics are a classification of the quality metrics in an order of values of the experimental data.

In step 208, the statistical measurement generator (108) generates statistical measurements for each variable per each QMC. The statistical measurement generator may obtain statistical measurements of the variables to determine correlations between the discretized classes of the quality metrics and the statistical measurements of the variables to reduce the number of design cycles implemented on the hardware component during the developing of the hardware component.

An example of statistical measurements per variable, per QMC, is shown in FIG. 7. In FIG. 7, for each variable, Variables 1-4, the x-axis shows the quality metric class number for each variable boxplot and the y-axis shows corresponding statistical probabilities (or measurements). For example, the y-axis may represent the median and the median for the quality metric class 1, for Variable 1, is approximately, 25, and the median for the quality metric class 2, for Variable 1, is approximately, 24, and so on. The y-axis may represent a statistical measurement other than median, for example, a variance.

At step 208, in an embodiment of the invention, the dataset integration engine (110) generates a dataset based on the statistical measurements per variable, per QMC, from the statistical measurement generator (108). As earlier described, the dataset corresponds to the classes of the quality metrics of the statistics measurements of the variables from the statistical measurement generator (108). The dataset integration engine (110) provides the dataset to the correlation determination engine (112) for applying a rank-correlated mining algorithm to mine for patterns of rank correlation.

In step 212, the correlation determination engine (e.g., 112, FIG. 1) determines the correlation between the statistical measurements across all classes, obtained from the statistical measurement generator (108). That is, correlation determination engine determines a pattern of changes of the QMCs to help a designer reduce the number of design cycles for developing a hardware component.

FIG. 3 shows an exemplary graph of the experimental data received from a data collection device (e.g., 102, FIG. 1), as processed by a quality metric clustering processor (e.g., 106, FIG. 1) to classify the experimental points based on a quality metric (QM) ranking. In an embodiment of the invention, discretized classification is performed by the quality metric clustering processor by applying an unsupervised clustering model to the quality metrics. For example, without limitation, the unsupervised clustering model may be a Gaussian Mixture Model (GMM).

An example output of the quality metric clustering processor may be the table of FIG. 4. The table of FIG. 4 includes four columns, each representing a variable (Variables 1-4), a QM column corresponding to each variable, and a QMC column corresponding to each QM. The quality metric clustering processor classifies each QM into a class or rank. For example, the QMC in the first row of the table, for the corresponding QM in that row, is 4 and the QM is QM₁₄ (the first point, class 4 in FIG. 3). The QMC in the second row of the table, for the corresponding QM, QM₁₃ (first point, third class) is 3. The QMC in the third row of the table, for the corresponding QM, QM₁₁ (first point, first class) is 1, and so on. Accordingly, QM values in the QM column of the table in FIG. 4 correspond to the experimental data in FIG. 4. The experimental data of FIG. 3 are presumed classified and therefore discretized, as shown by distinct symbols. For example, the fourth class is represented by dark circles, and the first class is represented by triangle symbols. Similarly, each cell of the table is distinctly represented in accordance with the QMC. For example, the first row of the table includes variables and QM of class 4, accordingly, the cells of the first row of the table are cross-hashed with wider and right-leaning hashes. The second row of the table includes variables and QM of class 3, accordingly, the cells of the second row of the table are cross-hashed with narrower and right-leaning hashes, and so on. The order of the classes may be assigned according to the value of a corresponding QM. For example, assuming the QM to represent yield like the example above, class 4 may represent an “excellent” yield, class 3 may represent a “very good” yield, class 2 may represent an “acceptable” yield, and class 1 may represent an “unacceptable” yield. In an example embodiment, a designer may be interested in statistical measurements that show a trend moving in a particular direction consistent with the trend of the QMC. For example, a variable (e.g., layers of the semiconductor) may increase with the increase in the QMC, a behavior that is attractive to a designer. Otherwise, a variable (e.g., power consumption of a fan) may decrease with the trend in a corresponding QMC, which may be attractive to a designer of the fan because the power consumption is generally best when it is lower.

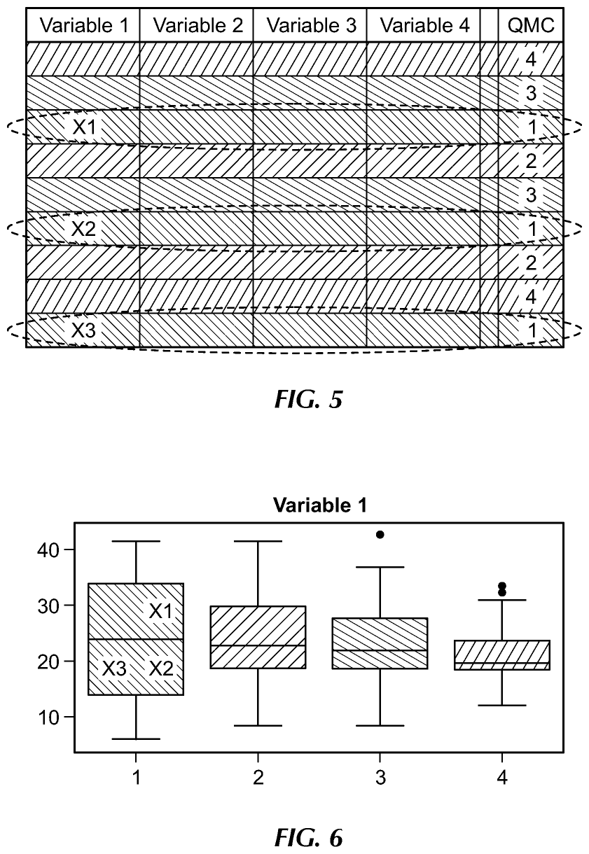

FIG. 5 shows a similar table to the table of FIG. 4 except that it is absent the QM column and the symbol-coding of FIG. 4. In some embodiments of the invention, the statistical measurement generator (108) may generate a boxplot for each variable, such as the boxplot of FIG. 6 for Variable 1, or the boxplots of FIG. 7 for Variables 1-4, based on the rows encircled with a dash oval in FIG. 5. In the examples of FIGS. 5-7, the x-axis in each boxplot represents the quality metric class number and the y-axis represents a statistical measurement, for example, median, a point at which half of the values in a boxplot are above the point and the remaining half of the values is below the point. For example, the median of class 1 in FIG. 6 is 25, the median of class 2 in FIG. 6 is slightly lower than 25, the median of class 3 is lower than that of classes 1 and 2 and the median of class 4 is lower than all remaining three classes. In some embodiments, a representation different than a boxplot for variables may be generated by the statistical measurement generator (108).

With continued reference to FIGS. 5 and 6, each row of the table of FIG. 5 includes an observation, or a set of experimental data, obtained from the data collection device (102), for each variable, Variables 1-4. In response to the classification of the observations based on the QMs (in this case, one QM), as shown in the corresponding QMC column of FIG. 5, and the raw values of the variables from the data collection device (102), the statistical measurement generator (e.g., 108, FIG. 1) determines the rows that correspond to a particular class. In the example of FIG. 5, class 1 rows are identified by a statistical measurement generator (e.g., 108, FIG. 1) and the statistical measurement generator plots each of the observations for a variable to generate the boxplot of FIG. 6. For example, the observations or data points for Variable 1, in class 1, are shown in a boxplot filled with similar hash lines as the fill shown in the row identified by class 1 in FIG. 5. Each row is similarly identified per class, the variable points are plotted in a corresponding boxplot, such as shown in the boxplot of FIG. 7 corresponding to the row identified by class 2 in FIG. 5, and so on. The boxplots of FIG. 7 are shown for each of the four variables for four classes, each boxplot represents a distinct class for a particular variable. The boxplot of FIG. 6 is shown for one variable for four classes.

In FIG. 7, the median for the classes of Variable 1 are shown to decrease as the order of the classes increases (from 1 to 4), whereas, the median for the classes of each of the Variables 2 and 4 are shown to increase as the order of classes increase. Generally, the difference between the Variables 2 and 4 is that the range of values of the lower classes (classes 1 and 2) in Variable 4 is greater than the range of values of the lower classes in Variable 2. In contrast, generally, the difference between the Variables 2 and 4 is that the range of values of the higher classes (classes 3 and 4) in Variable 2 is greater than the range of values of the higher classes in Variable 4. The lower classes of Variable 3 are sporadic at higher values (>30) and more within a specific range (e.g., 10-180) at higher classes. There is a fairly great disparity between the median of class 3 and the median of class 4 (e.g., 40). All of this data represents various variable scenarios which each might be a good fit for a particular QM or a set of QMs based on the desired hardware design features.

FIG. 8 shows an exemplary statistical measurement table, generated by the dataset integration engine (110). The table of FIG. 8 is similar to the tables of FIGS. 4, 5 in that all reflect a QMC column except that instead of raw variables represented in the remaining columns, a statistical measurement (e.g., percentages) of a subset of variables is indicated under each column. For example, the first column adjacent to the QMC column is the 25th percentile probability of Variable 1, P^{V1}_{25%}, the second column from the QMC column is the 30th percentile probability of Variable 2, P^{V2}_{30%}, the third column from the QMC column is the 75th percentile probability of Variable 1, P^{V1}_{75%}, and the fourth column from the QMC column is the 25th percentile probability of Variable 2, P^{V2}_{25%}. It is understood that the percentile probabilities indicated in FIG. 8 are merely examples and any other type of statistical measurement and/or percentile suitable for statistical comparison may be employed. While not shown in FIG. 8, typically, all columns of the table of FIG. 8 include values. It is further understood that the use of four variables is merely illustrative and any number of variables may be employed. In some cases, a greater number of variables may increase the complexity of operations and require a higher level of difficulty in identifying a pattern of behavior but a larger number of variables than four should be informative, at least in some cases.

The table of FIG. 8 generally shows the statistical behavior of the variables (e.g., Variables 1-4) according to an increasing QMC (e.g., from 1-4). For example, the 25th percentile of Variable 1 may be decreasing as the order of classes decreases. A percentile decrease consistent with a class decrease may be desirable based on corresponding QMs relative to the hardware design. In an embodiment of the invention, the table of FIG. 8 may be input to a rank-correlated mining algorithm that identifies a pattern or a trend in the variable probabilities. For example, the algorithm disclosed in the publication titled “Mining Rank-Correlated Sets of Numerical Attributes”, by Toon Calders, Bart Goethals, and the Szymon Jaroszewicz, published in January, 2006, incorporated by reference as though set forth in full, may be applied to the statistical measurements by the correlation determination engine (112). The algorithm may compare each pair of QMCs for a probability trend. For example, by applying the algorithm, the P^{V1}_{25%} of QMCs 1 and 2 may be compared and then, the QMCs 2 and 3 of the P^{V1}_{25%} may be compared, next the P^{V1}_{25%} of the QMCs 3 and 4 may be compared, followed by the comparison of QMCs 1 and 3 for P^{V1}_{25%}, and so on until all possible pairs are compared to identify a particular trend or pattern, i.e., decreasing P^{V1}_{25%} or an increasing P^{V1}_{25%}, with a decreasing order of classes. Based on the comparisons, the rank-correlated mining algorithm determines patterns of rank correlation. In some embodiments, patterns of rank correlation may be identified based on a comparison of more than one of the probabilities. For example, the pair comparison may be a comparison of the values of both of the P^{V1}_{25%} and P^{V2}_{30%} values for each QMC pair. A comparison of a pair using more than one probability or statistical measurement (more than one probability column in FIG. 8) may help indicate the dependency of one variable on another variable based on the order of classes.

The mining algorithm allows for the selection of rank correlation patterns based on a frequency in a particular statistical dataset. For example, the algorithm may generate the information shown in FIG. 9. In FIG. 9, a pattern is detected by the algorithm between the statistical measurement A, B, and C. As shown by the table in FIG. 9, the pattern between A and B is 2 out of 3 possibilities, the pattern between A and C is also 2 out of 3 possibilities, the pattern between B and C is 3 out of 3 and the pattern between A, B, and C is 2 out of 3. In other words, the order of values of the classes of the experimental data is based on the selection of the rank correlation patterns arranged from most relevant, 3, to least relevant, 1. The selection of the rank correlation patterns can be used in further analysis of the hardware fabrication or design process to reduce the design cycles of a hardware component. In some cases, the rank correlation pattern of the rank correlation patterns is based on an increase or a decrease of one or more of the statistical measurements corresponding to an increase or a decrease of an order of value (classes) of one or more quality metrics.

As discussed above, embodiments of the disclosure may be implemented using computing devices. FIG. 10 shows a diagram of a computing device in accordance with one or more embodiments of the disclosure.

The computing device (1000) may include one or more computer processors (1010), non-persistent storage (1006) (e.g., volatile memory, such as random access memory (RAM), cache memory), persistent storage (1008) (e.g., a hard disk, an optical drive such as a compact disk (CD) drive or digital versatile disk (DVD) drive, a flash memory, etc.), a communication interface (1012) (e.g., Bluetooth® interface, infrared interface, network interface, optical interface, etc.), input devices (1004), output devices (1002), and numerous other elements (not shown) and functionalities. Each of the components illustrated in FIG. 10 is described below.

In one embodiment of the disclosure, the computer processor(s) (1010) may be an integrated circuit for processing instructions. For example, the computer processor(s) may be one or more cores or micro-cores of a processor. The computing device (1000) may also include one or more input devices (1004), such as a touchscreen, keyboard, mouse, microphone, touchpad, electronic pen, or any other type of input device. Further, the communication interface (1012) may include an integrated circuit for connecting the computing device (1000) to a network (not shown) (e.g., a local area network (LAN), a wide area network (WAN) such as the Internet, mobile network, or any other type of network) and/or to another device, such as another computing device.

In one embodiment of the disclosure, the computing device (1000) may include one or more output devices (1002), such as a screen (e.g., a liquid crystal display (LCD), a plasma display, touchscreen, cathode ray tube (CRT) monitor, projector, or other display device), a printer, external storage, or any other output device. One or more of the output devices may be the same or different from the input device(s). The input and output device(s) may be locally or remotely connected to the computer processor(s) (1010), non-persistent storage (1006), and persistent storage (1008). Many different types of computing devices exist, and the aforementioned input and output device(s) may take other forms.

Specific embodiments of the invention will now be described in detail with reference to the accompanying figures. In the following detailed description of the embodiments of the invention, numerous specific details are set forth in order to provide a more thorough understanding of the invention. However, it will be apparent to one of ordinary skill in the art that the invention may be practiced without these specific details. In other instances, well-known features have not been described in detail to avoid unnecessarily complicating the description.

In the above description of the figures, any component described with regard to a figure, in various embodiments, may be equivalent to one or more like-named components shown and/or described with regard to any other figure. For brevity, descriptions of these components may not be repeated with regard to each figure. Thus, each and every embodiment of the components of each figure is incorporated by reference and assumed to be optionally present within every other figure having one or more like-named components. Additionally, in accordance with various embodiments described herein, any description of the components of a figure is to be interpreted as an optional embodiment, which may be implemented in addition to, in conjunction with, or in place of the embodiments described with regard to a corresponding like-named component in any other figure.

Throughout the application, ordinal numbers (e.g., first, second, third, etc.) may be used as an adjective for an element (i.e., any noun in the application). The use of ordinal numbers is not to imply or create any particular ordering of the elements nor to limit any element to being only a single element unless expressly disclosed, such as by the use of the terms “before”, “after”, “single”, and other such terminology. Rather, the use of ordinal numbers is to distinguish between the elements. By way of an example, a first element is distinct from a second element, and the first element may encompass more than one element and succeed (or precede) the second element in an ordering of elements.

As used herein, the phrase operatively connected, or operative connection, means that there exists between elements/components/devices a direct or indirect connection that allows the elements to interact with one another in some way. For example, the phrase ‘operatively connected’ may refer to any direct (e.g., wired directly between two devices or components) or indirect (e.g., wired and/or wireless connections between any number of devices or components connecting the operatively connected devices) connection. Thus, any path through which information may travel may be considered an operative connection.

While embodiments described herein have been described with respect to a limited number of embodiments, those skilled in the art, having the benefit of this Detailed Description, will appreciate that other embodiments can be devised which do not depart from the scope of embodiments as disclosed herein. Accordingly, the scope of embodiments described herein should be limited only by the attached claims.

What is claimed is:

1. A method of implementing design cycles for developing a hardware component comprising:
receiving sets of experimental data, each set of experimental data resulting from an application of a set of variables to the hardware component during a common design cycle or a different design cycle of the hardware component, each variable representing an aspect of hardware component or an aspect of a fabrication process applied to the hardware component;
determining discretized classes of one or more quality metrics, wherein the discretized classes of the quality metrics are determined independently from a determination of discretized classes of a different quality metric of the one or more quality metrics, wherein the discretized classes of the quality metrics are a classification of the quality metrics in an order of values of the experimental data; and
obtaining statistical measurements of the variables to determine correlations between the discretized classes of the quality metrics and the statistical measurements of the variables to reduce the number of design cycles implemented on the hardware component during the developing of the hardware component.

2. The method of claim 1, further comprising:
performing the discretized classes by applying an unsupervised clustering model to the quality metrics.

3. The method of claim 2, wherein the unsupervised clustering model is a Gaussian Mixture Model (GMM).

4. The method of claim 1, wherein the statistical measurements are based on characteristics of a distribution of the experimental data for each variable.

5. The method of claim 1, wherein the statistical measurements include mean, median, variance, or percentile.

6. The method of claim 1, further comprising:
performing the statistics measurements of the variables for each of the classes of the quality metrics.

7. The method of claim 1, further comprising:
generating a dataset corresponding to the classes of the quality metrics to the statistics measurements of the variables.

8. The method of claim 7, wherein a rank-correlated mining algorithm is applied to the dataset to mine for patterns of rank correlation.

9. The method of claim 1, further comprising:
selecting one or more rank correlation patterns based on a frequency in the dataset.

10. The method of claim 9, wherein the order of the rank correlation patterns is arranged from most relevant to less relevant so as to be used in further analysis of the hardware fabrication or design process.

11. The method of claim 9, wherein a rank correlation pattern of the one or more rank correlation patterns is based on an increase or a decrease of one or more of the statistical measurements corresponding to an increase or a decrease of an order of value of one or more quality metrics.

12. A system, comprising:
a processor; and
memory comprising instructions which, when executed by the processor, perform a method, the method comprising:
receiving sets of experimental data, each set of experimental data resulting from an application of a set of variables to the hardware component during a common design cycle or a different design cycle of the hardware component, each variable representing an aspect of hardware component or an aspect of a fabrication process applied to the hardware component;
determining discretized classes of one or more quality metrics, wherein the discretized classes of the quality metrics are determined independently from a determination of discretized classes of a different quality metric of the one or more quality metrics, wherein the discretized classes of the quality metrics are a classification of the quality metrics in an order of values of the experimental data; and
obtaining statistical measurements of the variables to determine correlations between the discretized classes of the quality metrics and the statistical measurements of the variables to reduce the number of design cycles implemented on the hardware component during the developing of the hardware component.

13. The system of claim 12, wherein the method further comprises:
performing the discretized classes by applying an unsupervised clustering model to the quality metrics.

14. The system of claim 13, wherein the unsupervised clustering model is a Gaussian Mixture Model (GMM).

15. The system of claim 12, wherein the statistical measurements are based on characteristics of a distribution of the experimental data for each variable.

16. The system of claim 12, wherein the statistical measurements include mean, median, variance, or percentile.

17. The system of claim 12, further comprising:
performing obtaining the statistics measurements of the variables for each of the classes of the quality metrics.

18. The system of claim 12, further comprising:
generating a dataset corresponding to the classes of the quality metrics to the statistics measurements of the variables.

19. The system of claim 18, wherein a rank-correlated mining algorithm is applied to the dataset to mine for patterns of rank correlation.

20. A non-transitory computer readable medium comprising computer readable program code, which when executed by a computer processor enables the computer processor to perform a method for implementing design cycles for developing a hardware component comprising:
receiving sets of experimental data, each set of experimental data resulting from an application of a set of variables to the hardware component during a common design cycle or a different design cycle of the hardware component, each variable representing an aspect of hardware component or an aspect of a fabrication process applied to the hardware component;
determining discretized classes of one or more quality metrics, wherein the discretized classes of the quality metrics are determined independently from a determination of discretized classes of a different quality metric of the one or more quality metrics, wherein the discretized classes of the quality metrics are a classification of the quality metrics in an order of values of the experimental data; and
obtaining statistical measurements of the variables to determine correlations between the discretized classes of the quality metrics and the statistical measurements of the variables to reduce the number of design cycles implemented on the hardware component during the developing of the hardware component.
